(19) United States
(12) Patent Application Publication
(10) Pub. No.: US 2026/0068732 A1
(43) Pub. Date: Mar. 5, 2026

(54) SEMICONDUCTOR DEVICE

(71) Applicant: FUJI ELECTRIC CO., LTD., Kawasaki-shi (JP)

(72) Inventors: Takafumi YAMADA, Matsumoto-city (JP); Yoko NAKAMURA, Matsumoto-city (JP); Yuta TAMAI, Matsumoto-city (JP); Akihiko IWAYA, Tokyo (JP); Eiji IMAI, Matsumoto-city (JP); Daisuke INOUE, Matsumoto-city (JP); Yuya ISHIKURA, Matsumoto-city (JP); Daiki YOSHIDA, Matsumoto-city (JP)

(73) Assignee: FUJI ELECTRIC CO., LTD., Kawasaki-shi (JP)

(21) Appl. No.: 19/281,048

(22) Filed: Jul. 25, 2025

(30) Foreign Application Priority Data
Aug. 27, 2024 (JP) 2024-146008

(51) Int. Cl. H01L 23/00; H01L 23/498; H01L 25/065

(52) U.S. Cl. CPC H01L 24/37

(57) ABSTRACT

A semiconductor device, including: a semiconductor chip including an electrode on an upper surface thereof; and a wiring member including a bonding portion, a rising portion, and a connecting portion, the bonding portion being bonded to the electrode via a bonding material, the rising portion being of a shape of a flat plate and extending upward from the bonding portion, the connecting portion connecting the bonding portion to the rising portion. The rising portion includes a lower region connected to the connecting portion and an upper region located above the lower region. Both the lower region and the connecting portion have a first thickness, and the upper region has a second thickness that is larger than the first thickness.

### CROSS-REFERENCE TO RELATED APPLICATION

This application is based upon and claims the benefit of priority of the prior Japanese Patent Application No. 2024-146008, filed on Aug. 27, 2024, the entire contents of which are incorporated herein by reference.

### BACKGROUND OF THE INVENTION

### 1. Field of the Invention

The embodiments discussed herein relate to a semiconductor device.

### 2. Background of the Related Art

In a semiconductor device, a bonding material such as solder is used for bonding between a semiconductor chip and an insulated substrate and bonding between the semiconductor chip and a wiring member such as a lead frame.

The following techniques have been proposed as those related to semiconductor devices. For example, a power semiconductor module has been proposed in which a thermal diffusion metal plate is bonded to an electrode of a semiconductor chip and one end of a lead is bonded to the thermal diffusion metal plate (for example, see Japanese Laid-open Patent Publication No. 2013-197560). In addition, a power semiconductor device has been proposed in which a first terminal portion of a plate-shaped terminal is bonded to an electrode provided on the front surface of a power semiconductor element and a second terminal portion thereof is bonded to a lead-out wiring (see, for example, International Publication Pamphlet No. WO 2021/111846).

Further, a semiconductor device has been proposed in which an anode electrode formed in an anode region of a semiconductor substrate and a metal component are fixed to each other via a solder layer (see, for example, Japanese Laid-open Patent Publication No. 2007-027308). In addition, a semiconductor module has been proposed in which (A/B)<1 is satisfied between a tensile strength A of a first solder bonding a lead terminal to one surface of a semiconductor element and a tensile strength B of a second solder bonding a circuit layer to the other surface of the semiconductor element (for example, refer to Japanese Laid-open Patent Publication No. 2019-054146).

Still further, a semiconductor device has been proposed in which solder on a semiconductor element has an end face shape including a fillet curved upward in the direction from the surface of a surface electrode toward a solder center point and a fillet curved downward in the direction from the surface of an external electrode toward the solder center point (for example, see International Publication Pamphlet No. WO 2016/067414).

Still further, a semiconductor device has been proposed in which a lead electrode bonded to a surface electrode of a power semiconductor chip has a plurality of thin plate portions on the surface of the power semiconductor chip (for example, see Japanese Laid-open Patent Publication No. 2013-219139). In addition, a semiconductor module has been proposed which includes a plurality of plate-shaped leads covering a semiconductor chip (see, for example, Japanese Laid-open Patent Publication No. 2016-035970).

### SUMMARY OF THE INVENTION

According to an aspect of the present disclosure, there is provided a semiconductor device, including: a semiconductor chip including an electrode on an upper surface thereof; and a wiring member including a bonding portion, a rising portion, and a connecting portion, the bonding portion being bonded to the electrode via a bonding material, the rising portion being of a shape of a flat plate and extending upward from the bonding portion, the connecting portion connecting the bonding portion to the rising portion, wherein the rising portion includes a lower region connected to the connecting portion and an upper region located above the lower region, and both the lower region and the connecting portion have a first thickness, and the upper region has a second thickness that is larger than the first thickness.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a side view of the semiconductor device according to the first embodiment;

FIG. 3 is a plan view of a semiconductor unit according to the first embodiment;

FIG. 4 is a sectional view of the semiconductor unit according to the first embodiment;

FIG. 5 is a sectional view of a semiconductor unit in a state where deformation has occurred due to heat, according to a comparative example;

FIG. 6 is a plan view and a side view illustrating a first example of a configuration of a wiring member;

FIG. 7 is a sectional view of a semiconductor unit in a state where deformation has occurred due to heat;

FIG. 8 is a graph representing the relationship between the thickness of a wiring member and the power cycle resistance and the relationship between the thickness of the wiring member and the short-circuit safe operation area, with respect to the first example configuration of FIG. 6;

FIG. 9 is a plan view and a side view illustrating a second example of the configuration of the wiring member;

FIG. 10 is a plan view and a side view illustrating a third example of the configuration of the wiring member;

FIG. 11 illustrates the sizes of a semiconductor chip and a wiring member according to a second embodiment;

FIG. 12 is a graph representing the relationship between the inter-end distance between a first bonding portion and an active portion and the strain amplitude of an electrode and the plastic relationship between the inter-end distance and the power cycle resistance improvement rate, with respect to the case of FIG. 11;

FIG. 13 illustrates an example of the sizes of the semiconductor chip and the wiring member according to the second embodiment;

FIG. 14 is a sectional view illustrating a first example of a laminated structure of the wiring member;

FIG. 15 is a sectional view illustrating a second example of the laminated structure of the wiring member;

FIG. 16 is a sectional view illustrating a third example of the laminated structure of the wiring member;

FIG. 17 is a plan view illustrating a first example of an arrangement of laminated regions in wiring members;

FIG. 18 is a plan view illustrating a second example of the arrangement of the laminated regions in the wiring members; and

FIG. 19 is a plan view illustrating a third example of the arrangement of the laminated regions in the wiring members.

### DETAILED DESCRIPTION OF THE INVENTION

Hereinafter, embodiments will be described with reference to the accompanying drawings. In the following description, the terms “front surface” and “upper surface” refer to the X-Y plane facing upward (the +Z direction) in a semiconductor device of the drawings. Similarly, the term “up” refers to the upward direction (the +Z direction) in the semiconductor device of the drawings. The terms “rear surface” and “lower surface” refer to the X-Y plane facing downward (the −Z direction) in the semiconductor device of the drawings. Similarly, the term “down” refers to the downward direction (the −Z direction) in the semiconductor device of the drawings. The same directionality applies to the other drawings as appropriate. The terms “front surface,” “upper surface,” “up,” “rear surface,” “lower surface,” and “down” are used for convenience to describe relative positional relationships, and do not limit the technical concept of the embodiments. For example, the terms “up” and “down” are not always related to the vertical directions to the ground. That is, the “up” and “down” directions are not limited to those related to the gravity direction.

### First Embodiment

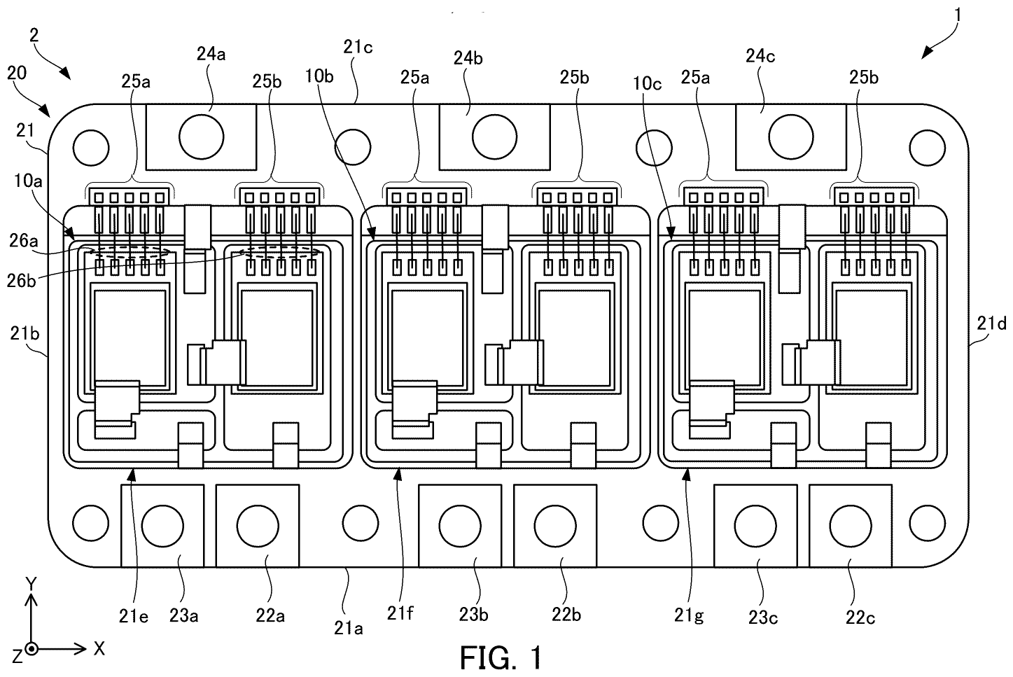

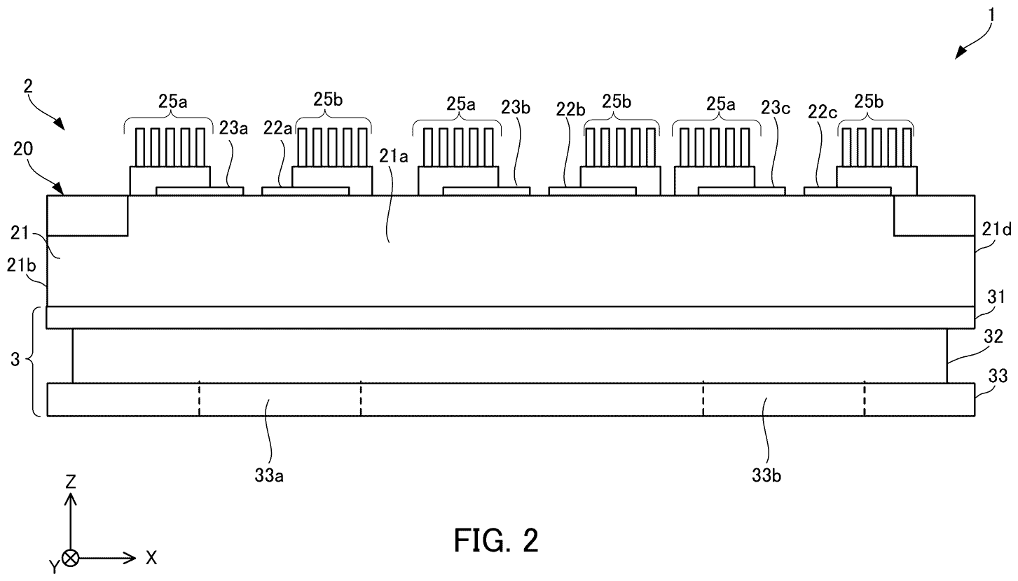

First, an example of an overall configuration of a semiconductor device according to a first embodiment will be described with reference to FIGS. 1 and 2. FIG. 1 is a plan view of the semiconductor device according to the first embodiment. FIG. 2 is a side view of the semiconductor device according to the first embodiment. The side view of FIG. 2 illustrates the semiconductor device 1 of FIG. 1 as viewed in the +Y direction.

The semiconductor device 1 includes a semiconductor module 2 and a cooling device 3. The semiconductor module 2 includes semiconductor units 10a, 10b, and 10c, and a case 20 housing the semiconductor units 10a, 10b, and 10c. The case 20 is arranged above the cooling device 3, and the semiconductor units 10a, 10b, and 10c are arranged in a line in the +X direction inside the case 20. The semiconductor units 10a, 10b, and 10c housed in the case 20 are sealed by a sealing member (not illustrated).

The semiconductor units 10a, 10b, and 10c have the same configuration. Therefore, the semiconductor units 10a, 10b, and 10c are collectively referred to as “semiconductor unit 10” when no distinction is not needed. Details of the semiconductor unit 10 will be described later.

The case 20 includes an outer frame 21, first connection terminals 22b, 22a, and 22c, second connection terminals 23a, 23b, and 23c, a U-phase output terminal 24a, a V-phase output terminal 24b, a W-phase output terminal 24c, and control terminals 25a and 25b.

The outer frame 21 has a rectangular shape in plan view, and the four sides thereof are surrounded by side walls 21a, 21b, 21c, and 21d. The side walls 21a and 21c correspond to the long sides of the outer frame 21, and the side walls 21b and 21d correspond to the short sides of the outer frame 21. In addition, in plan view, corners that are the connection portions between the side walls 21a, 21b, 21c, and 21d do not need to have right angles. These connection portions may be R-chamfered, for example, as illustrated in FIG. 1. The back surface of the outer frame 21 (the side walls 21a, 21b, 21c, and 21d) is on the same plane parallel to the X-Y plane.

The outer frame 21 has unit housing spaces 21e, 21f, and 21g arranged along the side walls 21a and 21c (the +X direction) at the center in the +Y direction of the front surface. Each unit housing space 21e, 21f, and 21g is defined in a rectangular shape in plan view and is opened in the front surface of the outer frame 21. The semiconductor units 10a, 10b, and 10c are housed in the unit housing spaces 21e, 21 f, and 21g, respectively. Therefore, the unit housing spaces 21e, 21f, 21g may be sized so as to house the semiconductor units 10a, 10b, and 10c, respectively.

The outer frame 21 has the first connection terminals 22a, 22b, and 22c and the second connection terminals 23a, 23b, and 23c arranged along the side wall 21a (the +X direction) on the side wall 21a of the front surface in plan view. The first connection terminals 22a, 22b, and 22c are positive electrode input terminals (P terminals), and the second connection terminals 23a, 23b, and 23c are negative electrode input terminals (N terminals).

In addition, the outer frame 21 has the U-phase output terminal 24a, the V-phase output terminal 24b, and the W-phase output terminal 24c arranged along the side wall 21c (the ±X direction) on the side wall 21c of the front surface. In this case, the first connection terminal 22a and the second connection terminal 23a are provided opposite to the U-phase output terminal 24a with the unit housing space 21e in between. The first connection terminal 22b and the second connection terminal 23b are provided opposite to the V-phase output terminal 24b with the unit housing space 21f in between. The first connection terminal 22c and the second connection terminal 23c are provided opposite to the W-phase output terminal 24c with the unit housing space 21g in between.

Furthermore, in plan view, control terminals 25a and 25b are provided between each unit housing space 21e, 21f, and 21g and the corresponding one of the U-phase output terminal 24a, the V-phase output terminal 24b, and the W-phase output terminal 24c, on the front surface of the outer frame 21. The control terminals 25a and 25b are provided for each of the unit housing spaces 21e, 21f, and 21g.

The above outer frame 21 has the first connection terminals 22a, 22b, and 22c, the second connection terminals 23a, 23b, and 23c, the U-phase output terminal 24a, the V-phase output terminal 24b, the W-phase output terminal 24c, and the control terminals 25a and 25b, and is integrally molded with them by injection molding using a thermoplastic resin. Thereby, the case 20 is formed. The thermoplastic resin is, for example, a polyphenylene sulfide resin, a polybutylene terephthalate resin, a polybutylene succinate resin, a polyamide resin, or an acrylonitrile butadiene styrene resin.

The first connection terminals 22a, 22b, and 22c, the second connection terminals 23a, 23b, and 23c, the U-phase output terminal 24a, the V-phase output terminal 24b, the W-phase output terminal 24c, and the control terminals 25a and 25b are made of a metal having excellent electrical conductivity. The metal here is, for example, copper, aluminum, or an alloy containing at least one of them as a main component. The surfaces of the first connection terminals 22a, 22b, and 22c, the second connection terminals 23a, 23b, and 23c, the U-phase output terminal 24a, the V-phase output terminal 24b, the W-phase output terminal 24c, and the control terminals 25a and 25b may be plated. At this time, the plating material used is, for example, nickel, a nickel-phosphorus alloy, or a nickel-boron alloy. The plated first connection terminals 22a, 22b, and 22c, the plated second connection terminals 23a, 23b, and 23c, the plated U-phase output terminal 24a, the plated V-phase output terminal 24b, the plated W-phase output terminal 24c, and the plated control terminals 25a and 25b have improved corrosion resistance.

In the following description, the first connection terminals 22a, 22b, and 22c may be collectively referred to as “first connection terminal 22” when no distinction is needed. Similarly, the second connection terminals 23a, 23b, and 23c may be collectively referred to as “second connection terminal 23”, and the U-phase output terminal 24a, the V-phase output terminal 24b, and the W-phase output terminal 24c may be collectively referred to as “output terminal 24”.

The sealing member for sealing the semiconductor units 10a, 10b, and 10c is a thermosetting resin. In the present embodiment, silicone gel is used as the thermosetting resin.

The cooling device 3 includes an inlet 33a through which a refrigerant flows into the cooling device 3, and an outlet 33b through which the refrigerant flowing through the cooling device 3 flows out to the outside. The cooling device 3 cools the semiconductor unit 10 by discharging heat from the semiconductor unit 10 through the refrigerant. The refrigerant used here is, for example, water, antifreeze (ethylene glycol aqueous solution), or long-life coolant. The cooling device 3 may include a pump and a heat dissipation device (radiator). The pump causes the refrigerant to flow into the inlet 33a of the cooling device 3 and causes the refrigerant flowing out of the outlet 33b to flow into the inlet 33a again to circulate the refrigerant. The heat dissipation device receives the refrigerant having flown out of the cooling device 3 and dissipates the heat of the refrigerant, to which the heat of the semiconductor unit 10 is conducted, to the outside.

This cooling device 3 includes a top plate 31, a side wall 32 connected to the rear surface of the top plate 31 in a loop shape, and a cooling bottom plate 33 provided opposite to the top plate 31 and connected to the lower surface of the side wall 32. The top plate 31 has a rectangular shape with four sides surrounded by long sides and short sides in plan view. Corners of the top plate 31 may be R-chamfered in plan view. The semiconductor units 10a, 10b, and 10c are bonded to the front surface of the top plate 31 along the ±X direction. The side wall 32 is continuously formed in a loop shape on the rear surface of the top plate 31. The cooling bottom plate 33 has a flat plate shape and has the same shape as the top plate 31 in plan view. Corners of the cooling bottom plate 33 may also be R-chamfered.

A plurality of heat dissipation fins (not illustrated) are formed in the rear surface area of the top plate 31. The heat dissipation fins each have a flat plate shape parallel to the X-Z plane, for example, and are arranged in parallel in the Y direction. The inlet 33a through which the refrigerant flows in and the outlet 33b through which the refrigerant flows out are formed in the bottom surface of the cooling bottom plate 33. A water distribution head is attached to each of the inlet 33a and the outlet 33b via an annular rubber seal, in seal regions surrounding the inlet 33a and the outlet 33b. A water distribution pipe connected to the pump is attached to each water distribution head.

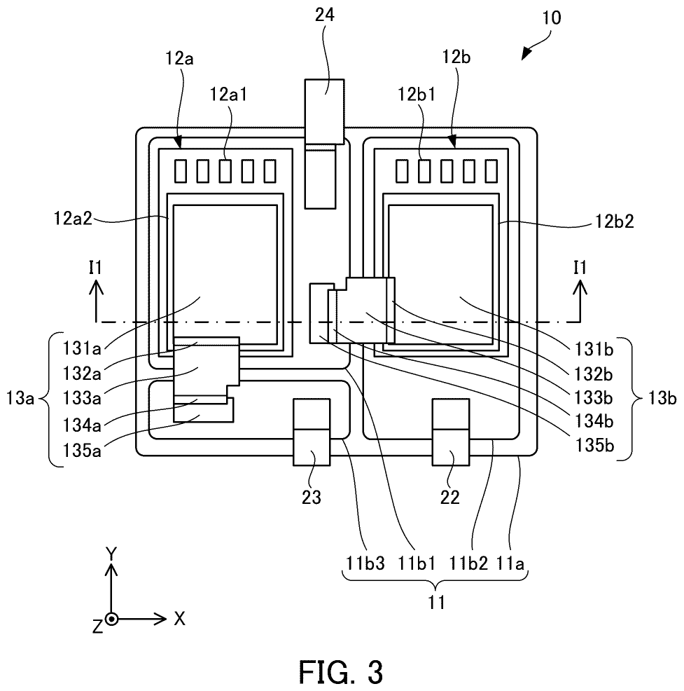

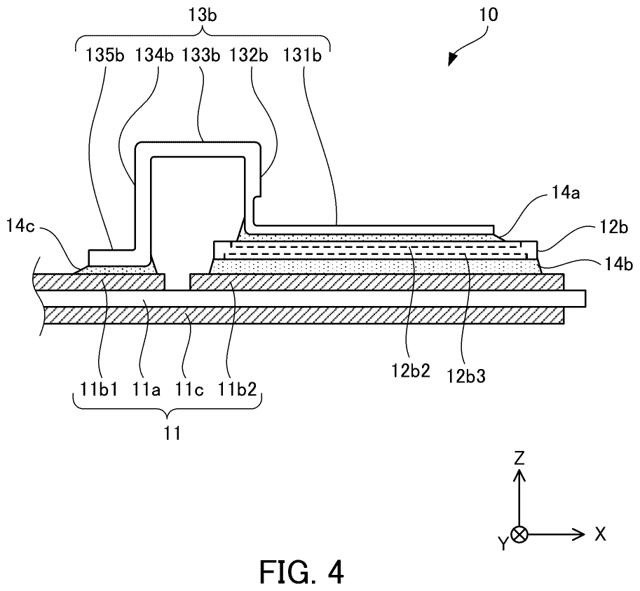

Next, the semiconductor unit 10 will be described with reference to FIGS. 3 and 4. FIG. 3 is a plan view of the semiconductor unit according to the first embodiment. FIG. 4 is a sectional view of the semiconductor unit according to the first embodiment. FIG. 3 depicts a case where the first connection terminal 22, the second connection terminal 23, and the output terminal 24 are connected to the semiconductor unit 10. FIG. 4 is an enlarged sectional view of an area around a semiconductor chip 12b in a sectional view of the semiconductor unit 10 taken along the line I1-I1 of FIG. 3.

The semiconductor unit 10 includes an insulated substrate 11, semiconductor chips 12a and 12b, and wiring members 13a and 13b. The semiconductor chips 12a and 12b are bonded to the insulated substrate 11 via a bonding material. The wiring members 13a and 13b are bonded to the semiconductor chips 12a and 12b, respectively, via a bonding material.

The insulated substrate 11 includes an insulating plate 11a, wiring plates 11b1, 11b2, and 11b3, and a metal plate 11c. The insulating plate 11a and the metal plate 11c are rectangular in plan view. Corners of the insulating plate 11a and the metal plate 11c may be R-chamfered or C-chamfered. In plan view, the metal plate 11c is smaller in size than the insulating plate 11a, and is formed inside the insulating plate 11a.

The insulating plate 11a is made of a material having an insulating property and excellent thermal conductivity. This insulating plate 11a may be made of ceramics or insulating resin. Examples of the ceramics include aluminum oxide, aluminum nitride, and silicon nitride. Examples of the insulating resin include a paper phenol substrate, a paper epoxy substrate, a glass composite substrate, and a glass epoxy substrate.

The wiring plates 11b1, 11b2, and 11b3 are formed on the front surface of the insulating plate 11a. The wiring plates 11b1, 11b2, and 11b3 are made of a metal containing copper and having excellent electrical conductivity. Such a metal may be, for example, an alloy containing aluminum in addition to copper.

The wiring plate 11b2 covers a substantially half region on the +X side of the front surface of the insulating plate 11a, and occupies the entire region from the −Y side to the +Y side. The wiring plate 11b1 occupies a substantially half region on the −X side of the front surface of the insulating plate 11a. The wiring plate 11b3 occupies the region surrounded by the wiring plates 11b1 and 11b2 on the front surface of the insulating plate 11a.

These wiring plates 11b1, 11b2, and 11b3 are formed on the front surface of the insulating plate 11a as follows. A metal plate is formed on the front surface of the insulating plate 11a, and is processed by etching or another so as to form the wiring plates 11b1, 11b2, and 11b3 in predetermined shapes. Alternatively, the wiring plates 11b1, 11b2, and 11b3 may be cut out from a metal plate in advance and pressure-bonded to the front surface of the insulating plate 11a. The wiring plates 11b1, 11b2, and 11b3 are examples. The number of wiring plates, and their shapes, sizes, and positions may be appropriately selected as needed.

The metal plate 11c is formed on the rear surface of the insulating plate 11a. The metal plate 11c has a rectangular shape. In plan view, the metal plate 11c is smaller in area than the insulating plate 11a and larger in area than the region where the wiring plates 11b1, 11b2, and 11b3 are formed. Corners of the metal plate 11c may be R-chamfered or C-chamfered. For example, the metal plate 11c is formed on the entire surface of the insulating plate 11a except the edge portion thereof. The metal plate 11c is made of a metal having excellent thermal conductivity as its main component. The metal is, for example, copper, aluminum, or an alloy containing at least one of these metals.

In the case where the insulating plate 11a configured as above is made of ceramics, for example, a direct copper bonding (DCB) substrate or an active metal brazed (AMB) substrate may be used as the insulated substrate 11. In the case where the insulating plate 11a is made of an insulating resin, a resin insulated substrate may be used. The insulated substrate 11 may be attached to the front surface of the top plate 31 of the cooling device 3 via a bonding member (not illustrated). Heat generated by the semiconductor chips 12a and 12b is conducted to the cooling device 3 through the wiring plates 11b1 and 11b2, the insulating plate 11a, and the metal plate 11c and is then dissipated.

The semiconductor chips 12a and 12b each include a power device element that is made of silicon. The power device element is a reverse-conducting (RC)-insulated gate bipolar transistor (IGBT). The RC-IGBT has both functions of an IGBT as a switching element and a free-wheeling diode (FWD) as a diode element.

The front surface of the semiconductor chip 12a has a rectangular shape in plan view, and includes gate electrodes 12al and an emitter electrode 12a2 (output electrode) as a main electrode. In this example, the gate electrodes 12al are provided on one short side of the front surface of the semiconductor chip 12a. The gate electrodes 12al are connected to the control terminals 25a via wires 26a (see FIG. 1). The emitter electrode 12a2 is provided on the other short side of the front surface of the semiconductor chip 12a. A collector electrode (input electrode, not illustrated) as a main electrode is provided on the rear surface of the semiconductor chip 12a. The collector electrode is bonded to the wiring plate 11b1 via a bonding material (not illustrated).

The semiconductor chip 12b has the same configuration as the semiconductor chip 12a. More specifically, the semiconductor chip 12b has gate electrodes 12b1 and an emitter electrode 12b2 on the front surface thereof, and a collector electrode 12b3 on the rear surface thereof. The gate electrodes 12b1 are connected to the control terminals 25b via wires 26b (see FIG. 1). The collector electrode is bonded to the wiring plate 11b2 via a bonding material 14b.

The wires 26a and 26b (see FIG. 1) are made of a material having excellent electrical conductivity as their main component. Such a material is, for example, gold, copper, aluminum, or an alloy containing at least one of them. Preferably, the wires 26a and 26b may be made of an aluminum alloy containing a small amount of silicon.

Each of the semiconductor chips 12a and 12b may include a set of a switching element and a diode element, instead of the RC-IGBT. The switching element is, for example, an IGBT or a power metal-oxide-semiconductor field-effect transistor (MOSFET). Each semiconductor chip 12a and 12b of this type includes, for example, an input electrode (drain electrode or collector electrode) as a main electrode on the rear surface thereof, and a control electrode (gate electrode) and an output electrode (source electrode or emitter electrode) as a main electrode on the front surface thereof. The diode element is, for example, a Schottky barrier diode (SBD) or a P-intrinsic-N (PiN) diode, and these are used as the FWD. Each semiconductor chip 12a and 12b of this type includes an output electrode (cathode electrode) as a main electrode on the rear surface thereof and an input electrode (anode electrode) as a main electrode on the front surface thereof.

Each of the semiconductor chips 12a and 12b may include a switching element formed of a power MOSFET made of silicon carbide as its main component. In this case, each semiconductor chip 12a and 12b includes an FWD together with the power MOSFET. Each semiconductor chip 12a and 12b of this type includes a control electrode (gate electrode) and an output electrode (source electrode) as a main electrode on the front surface thereof, and also includes an input electrode (drain electrode) as a main electrode on the rear surface thereof.

The wiring member 13a connects the emitter electrode 12a2 on the front surface of the semiconductor chip 12a to the wiring plate 11b3. The second connection terminal 23 is connected to the wiring plate 11b3. On the other hand, the wiring member 13b connects the emitter electrode 12b2 on the front surface of the semiconductor chip 12b to the wiring plate 11b1. The output terminal 24 is connected to the wiring plate 11b1, and the first connection terminal 22 is connected to the wiring plate 11b2.

With the above configuration, the semiconductor unit 10 constitutes an inverter circuit for one phase. The wiring plate 11b2, the semiconductor chip 12b, the wiring member 13b, and the wiring plate 11b1 form the upper arm part of a half-bridge circuit. The wiring plate 11b1, the semiconductor chip 12a, the wiring member 13a, and the wiring plate 11b3 form the lower arm part of the half-bridge circuit. The output terminal 24 connected to the wiring plate 11b1 is used as an M terminal serving as an output terminal in the half-bridge circuit. Further, the first connection terminal 22 connected to the wiring plate 11b2 is used as a P terminal serving as a positive electrode input terminal in the half-bridge circuit, and the second connection terminal 23 connected to the wiring plate 11b3 is used as an N terminal serving as a negative electrode output terminal in the half-bridge circuit. The switching operations of the semiconductor chips 12a and 12b are controlled according to control signals input to the gate electrodes 12a1 and 12b1 from the control terminals 25a and 25b.

The wiring member 13a integrally includes a first bonding portion 131a, a first rising portion 132a, a bridge portion 133a, a second rising portion 134a, and a second bonding portion 135a. The wiring member 13b integrally includes a first bonding portion 131b, a first rising portion 132b, a bridge portion 133b, a second rising portion 134b, and a second bonding portion 135b. In the present embodiment, each of the wiring members 13a and 13b is a lead frame having a substantially flat plate shape. The wiring members 13a and 13b may be bent to form the above-described portions.

The wiring members 13a and 13b are made of a metal containing copper and having excellent electrical conductivity. Such a metal may be, for example, an alloy containing aluminum in addition to copper. In order to improve corrosion resistance, the surfaces of the wiring members 13a and 13b may be plated. The plating material used is, for example, nickel, a nickel-phosphorus alloy, or a nickel-boron alloy.

The first bonding portions 131a and 131b have a substantially flat plate shape. The first bonding portions 131a and 131b are bonded respectively to the emitter electrodes 12a2 and 12b2 of the semiconductor chips 12a and 12b via a bonding material. For example, as illustrated in FIG. 4, the first bonding portion 131b is bonded to the emitter electrode 12b2 via the bonding material 14a. The shapes of the first bonding portions 131a and 131b in plan view are rectangular as with the emitter electrodes 12a2 and 12b2.

The lower end portions of the first rising portions 132a and 132b are integrally connected to end portions of the first bonding portions 131a and 131b, and the upper end portions thereof extend vertically upward (+Z direction) with respect to the first bonding portions 131a and 131b. The first rising portion 132a is bonded to an end portion on the wiring plate 11b3 (−Y direction) side of the first bonding portion 131a bonded to the semiconductor chip 12a. The first rising portion 132b is bonded to an end portion on the wiring plate 11b1 (−X direction) side of the first bonding portion 131b bonded to the semiconductor chip 12b.

The bridge portions 133a and 133b are integrally connected to the upper end portions of the first rising portions 132a and 132b and extend in the directions toward the wiring plates 11b3 and 11b1, respectively. The bridge portions 133a and 133b have a flat plate shape. The bridge portions 133a and 133b extend in the ±Y direction and the ±X direction, respectively. One end portion and the other end portion of each bridge portion 133a and 133b may be displaced relative to each other. At this time, the bridge portions 133a and 133b straddle the gaps between the wiring plates 11b1 and 11b3 and between the wiring plates 11b1 and 11b2, respectively. The bridge portions 133a and 133b are parallel to the insulated substrate 11. The bridge portions 133a and 133b may have the same height. The heights of the first rising portions 132a and 132b and the second rising 134a portions and 134b are appropriately selected so that the bridge portions 133a and 133b have the same height.

The upper end portions of the second rising portions 134a and 134b are integrally connected to end portions of the bridge portions 133a and 133b, and the lower end portions thereof extend vertically downward (−Z direction) and are integrally connected to the second bonding portions 135a and 135b. The second bonding portions 135a and 135b are bonded respectively to the wiring plates 11b3 and 11b1 via a bonding material, and are integrally connected to the lower end portions of the second rising portions 134a and 134b.

For example, solder is used as the bonding material for bonding the first bonding portions 131a and 131b to the semiconductor chips 12a and 12b, the second bonding portions 135a and 135b to the wiring plates 11b3 and 11b1, and the semiconductor chips 12a and 12b to the wiring plates 11b1 and 11b2. Solder components constituting the solder include lead-free solder containing a predetermined alloy as its main component. The predetermined alloy contains tin. Such an alloy is, for example, at least one of an alloy of tin-silver, an alloy of tin-silver-copper, an alloy of tin-zinc-bismuth, an alloy of tin-copper, an alloy of tin-silver-indium-bismuth, or an alloy of tin-antimony. Furthermore, such a solder component may include an additive. Examples of the additive include nickel, germanium, cobalt, and silicon. Therefore, examples of the solder components include tin and at least one of silver, zinc, copper, bismuth, indium, or antimony.

In addition, a sintered body may be used for the bonding of the above-described portions. In the case where the sintered body is used for the bonding, the sintered material is, for example, a powder containing at least one of silver, iron, copper, aluminum, titanium, nickel, tungsten, or molybdenum.

In the semiconductor unit 10, the insulating plate 11a, the wiring plates 11b1, 11b2, and 11b3, the semiconductor chips 12a and 12b, and the wiring members 13a and 13b are sealed by a sealing member. In the present embodiment, silicone gel is used as the sealing member.

Another thermosetting resin generally used as a sealing member is an epoxy resin. The silicone gel is less expensive than the epoxy resin, but is easily deteriorated at high temperature, and has a high thermal resistance and a low heat dissipation performance. In the case where the silicone gel is used as the sealing member, the high thermal resistance causes a problem that the semiconductor chips 12a and 12b themselves, the insulated substrate 11, and the wiring members 13a and 13b are likely to become high temperature due to heat generated from the semiconductor chips 12a and 12b, and these members are therefore likely to expand and deform.

The following description of the present embodiment is about the relationship between the semiconductor chip 12b and the wiring member 13b, but the same applies to the relationship between the semiconductor chip 12a and the wiring member 13a.

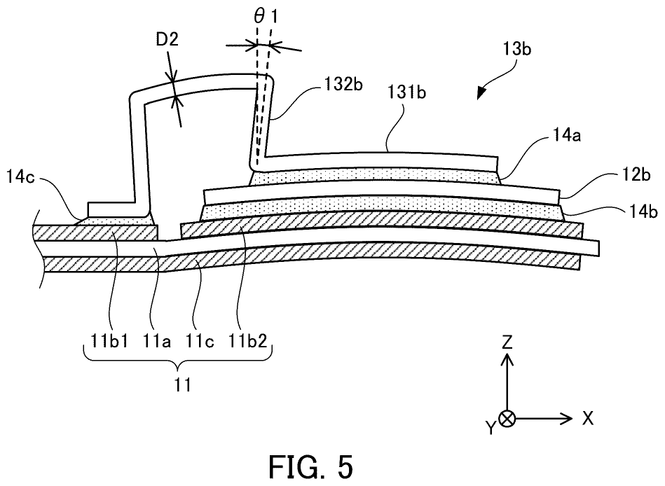

Here, FIG. 5 is a sectional view of a semiconductor unit in a state in which deformation has occurred due to heat, according to a comparative example. FIG. 5 is a sectional view of the same area as in FIG. 4, viewed in the same direction, depicting the comparative example in which the wiring member 13b has a uniform thickness D2 throughout.

In the example of FIG. 5, due to heat generation of the semiconductor chip 12b, the insulated substrate 11, the semiconductor chip 12b, and the first bonding portion 131b of the wiring member 13b are warped relative to the ±X direction. This warping is convex upward (+Z direction), with the vicinity of the center of the semiconductor chip 12b as the vertex. Since the semiconductor chip 12b and the first bonding portion 131b of the wiring member 13b have different linear expansion coefficients, the semiconductor chip 12b and the first bonding portion 131b are warped in different ways.

Specifically, the wiring member 13b has a higher linear expansion coefficient than the semiconductor chip 12b. Therefore, the amount of expansion in the ±X direction at high temperature is greater in the first bonding portion 131b of the wiring member 13b than in the semiconductor chip 12b. Due to such a difference in the amount of expansion, stress is generated in the bonding material 14a between the semiconductor chip 12b and the first bonding portion 131b, and a crack may occur in the bonding material 14a.

Such a crack is particularly likely to occur in the bonding material 14a during power cycle testing, where the temperature repeatedly changes and becomes high. Moreover, the crack, which has occurred, tends to extend with the temperature changes. Furthermore, the stress is also applied to the emitter electrode 12b2 of the semiconductor chip 12b, which is bonded to the bonding material 14a, which may cause damage to the emitter electrode 12b2.

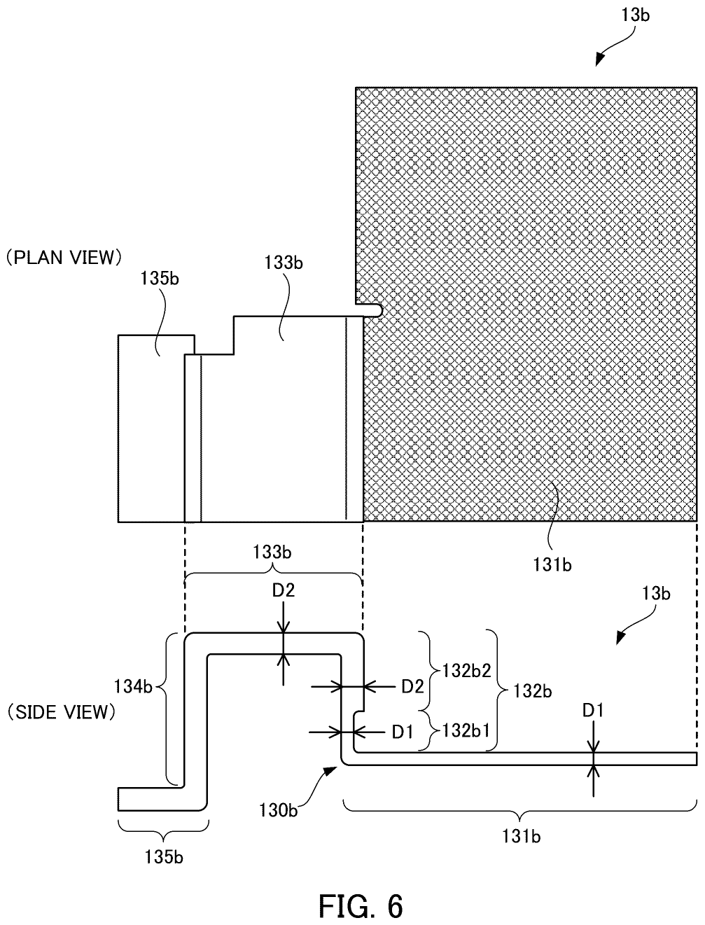

In order to address this problem, in the present embodiment, the wiring member 13b is made thinner at least in a vicinity region of a connecting portion 130b (see FIG. 6) where the first bonding portion 131b and the first rising portion 132b are connected to each other than in the other region. By doing so, it is possible to reduce the stress generated in the bonding material 14a due to the expansion and contraction of the wiring member 13b and to reduce the occurrence of the damage to the bonding material 14a.

Hereinafter, examples of the configuration of the wiring member 13b will be described.

FIG. 6 is a plan view and a side view illustrating a first example of the configuration of the wiring member. In the wiring member 13b illustrated in FIG. 6, the bridge portion 133b, the second rising portion 134b, and the second bonding portion 135b have a thickness D2 (second thickness), as in FIG. 5.

On the other hand, the wiring member 13b includes the connecting portion 130b where the first bonding portion 131b and the first rising portion 132b are connected to each other, and the first rising portion 132b extends from the connecting portion 130b in a direction away from the first bonding portion 131b. In the example of FIG. 6, the first rising portion 132b extends in the vertically upward direction (the +Z direction) from the connecting portion 130b. The connecting portion 130b extends from the first bonding portion 131b, bends toward the first rising portion 132b, and is connected to the first rising portion 132b.

At least a vicinity region of the connecting portion 130b in the wiring member 13b has a thickness D1 (first thickness) that is less than the thickness D2 of the bridge portion 133b, the second rising portion 134b, and the second bonding portion 135b. In the first example configuration illustrated in FIG. 6, the first rising portion 132b of the wiring member 13b includes a lower region 132b1 connected to the connecting portion 130b and an upper region 132b2 located above the lower region 132b1. The lower region 132bl and the connecting portion 130b have the thickness D1, and the upper region 132b2 has the thickness D2. That is, the thickness of the lower region 132bl of the first rising portion 132b in the wiring member 13b, which is connected to the connecting portion 130b, and the thickness of the connecting portion 130b are less than the thickness of the upper region 132b2 located above the lower region 132b1.

In addition, the first bonding portion 131b has the thickness D1 throughout, including the region connected to the connecting portion 130b. That is, with respect to the first bonding portion 131b, the entire thickness of the first bonding portion 131b including the region connected to the connecting portion 130b is less than the thickness of the upper region 132b2 located above the lower region 132b1. In the plan view of FIG. 6, the first bonding portion 131b having the thickness D1 is hatched.

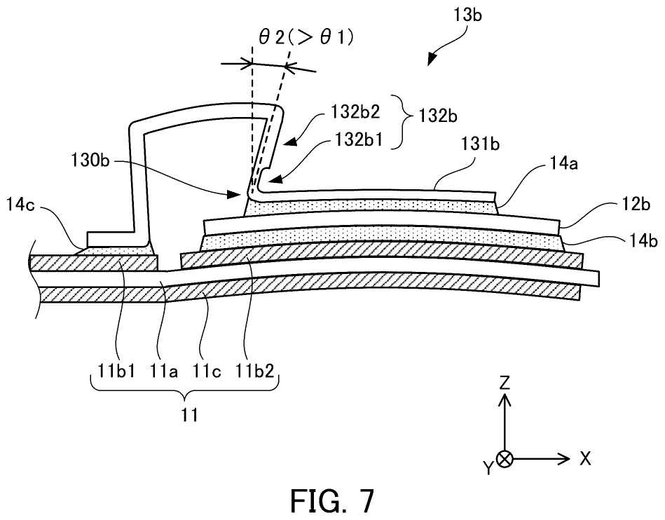

FIG. 7 is a sectional view of the semiconductor unit in a state where deformation has occurred due to heat. FIG. 7 is a sectional view of the same area as in FIG. 4, viewed in the same direction, illustrating the semiconductor unit 10 to which the wiring member 13b illustrated in FIG. 6 is applied.

In the wiring member 13b, at least the connecting portion 130b and the vicinity region of the connecting portion 130b have the thickness D1, which is less than the thickness D2 of the other regions. Therefore, the connecting portion 130b has a reduced bending rigidity. As a result, the amount of deformation (amount of expansion and contraction) due to temperature changes in the vicinity region of the connecting portion 130b is reduced, and the wiring member 13b is easily bent at the connecting portion 130b.

For example, in the case where the thicknesses of the connecting portion 130b and the vicinity region of the connecting portion 130b are equal to the thickness D2 of the bridge portion 133b, the second rising portion 134b, and the second bonding portion 135b, as illustrated in FIG. 5, the first rising portion 132b tilts by θ1 degrees with respect to the vertical direction (the +Z direction) due to the deformation of the first bonding portion 131b caused by thermal expansion. On the other hand, in the case where the connecting portion 130b and the vicinity region of the connecting portion 130b have the thickness D1 that is less than the thickness D2 of the bridge portion 133b, the second rising portion 134b, and the second bonding portion 135b, as illustrated in FIG. 7, the first rising portion 132b tilts by θ2 degrees that is larger than θ1 with respect to the vertical direction (the +Z direction) due to the deformation of the first bonding portion 131b caused by thermal expansion.

The increase in the bending angle at the connecting portion 130b as described above alleviates the stress applied to the bonding material 14a from the first bonding portion 131b. In addition, the amount of deformation itself due to the expansion and contraction in the vicinity region of the connecting portion 130b in the wiring member 13b is reduced, which in turn reduces the stress itself applied to the bonding material 14a from the first bonding portion 131b. As a result, it is possible to reduce the likelihood that a crack occurs in the bonding material 14a and the likelihood that the crack develops.

In addition, since the tilt angle of the first rising portion 132b increases, the amount of movement in the −X direction of the bridge portion 133b, the second rising portion 134b, and the second bonding portion 135b due to the expansion of the first bonding portion 131b in the −X direction also decreases. As a result, the stress applied to the bonding material 14c from the second bonding portion 135b is also reduced, which in turn reduces the likelihood of a crack occurring in the bonding material 14c.

Further, in the first example configuration of FIG. 7, the overall thickness of the first bonding portion 131b is reduced, which reduces the overall rigidity of the first bonding portion 131b. As a result, the amount of deformation due to expansion and contraction of the entire first bonding portion 131b is also reduced. Therefore, the first bonding portion 131b is able to follow the deformation of the semiconductor chip 12b, and the stress applied to the bonding material 14a from the first bonding portion 131b is reduced, so that it is possible to reduce the likelihood that a crack occurs in the bonding material 14a and the likelihood that the crack develops.

However, as the thin region of the wiring member 13b increases, the Joule heat generated when a current flows through the wiring member 13b increases. In addition, the rigidity of the wiring member 13b decreases, so that the wiring member 13b is easily damaged. For this reason, it is desirable that the thin region of the wiring member 13b be as small as possible.

In the first example configuration of FIG. 7, only the lower region 132b1 in the first rising portion 132b is thinned, which means that only a region needed for reducing the bending rigidity at the connecting portion 130b is thinned. Accordingly, it is possible to suppress the generation of the Joule heat while reducing the stress applied to the bonding material 14a from the first bonding portion 131b and also reducing the likelihood of damage to the wiring member 13b due to the decreased rigidity.

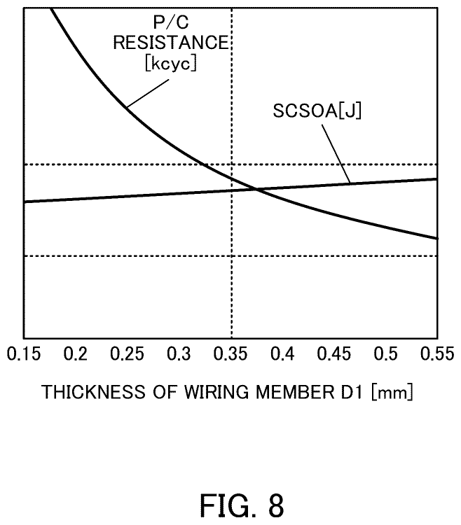

In addition, as illustrated in FIG. 8, it is desirable that the thickness D1 of the thin region of the wiring member 13b is appropriately set in consideration of the balance between the power cycle resistance due to stress generation and the generation of the Joule heat.

FIG. 8 is a graph representing the relationship between the thickness of a wiring member and the power cycle resistance and the relationship between the thickness of the wiring member and the short-circuit safe operation area, with respect to the first example configuration of FIG. 6. The graph of FIG. 8 represents the power cycle (P/C) resistance and the short-circuit safe operation area (SCSOA) with respect to the overall thickness D1 of the first bonding portion 131b and the lower region 132b1 of the first rising portion 132b connected to the connecting portion 130b in the wiring member 13b, in the case where the thickness D2 of the bridge portion 133b, the second rising portion 134b, and the second bonding portion 135b of the wiring member 13b is 0.5 mm.

The power cycle (P/C) resistance curve illustrated in FIG. 8 represents the ΔTvj power cycle resistance in the case where a temperature variation of 90° C., ranging from 70° C. to 160° C., is applied. According to this graph, as the overall thickness D1 of the lower region 132b1 of the first rising portion 132b connected to the connecting portion 130b and the first bonding portion 131b in the wiring member 13b decreases, the stress applied to the bonding material 14a from the first bonding portion 131b decreases, as described above, which results in an improvement in the power cycle resistance. On the other hand, as the thickness D1 decreases, the value of SCSOA decreases with an increase in the generation of the Joule heat.

It is seen from the graph of FIG. 8 that the thickness D1 of the thin region of the wiring member 13b is preferably in the range of 0.15 mm to 0.35 mm, inclusive, with 0.25 mm as a reference. More preferably, in consideration of a dimensional tolerance of +0.05 mm, the thickness D1 is desirably in the range of 0.2 mm to 0.3 mm, inclusive. Such setting improves the power cycle resistance to a sufficiently high level and suppresses the generation of the Joule heat, which makes it possible to extend the lifetime of the semiconductor module 2 and improve the reliability. In addition, the power cycle resistance is able to satisfy customer requirements, and the margin relative to the SCSOA standard value is sufficiently large.

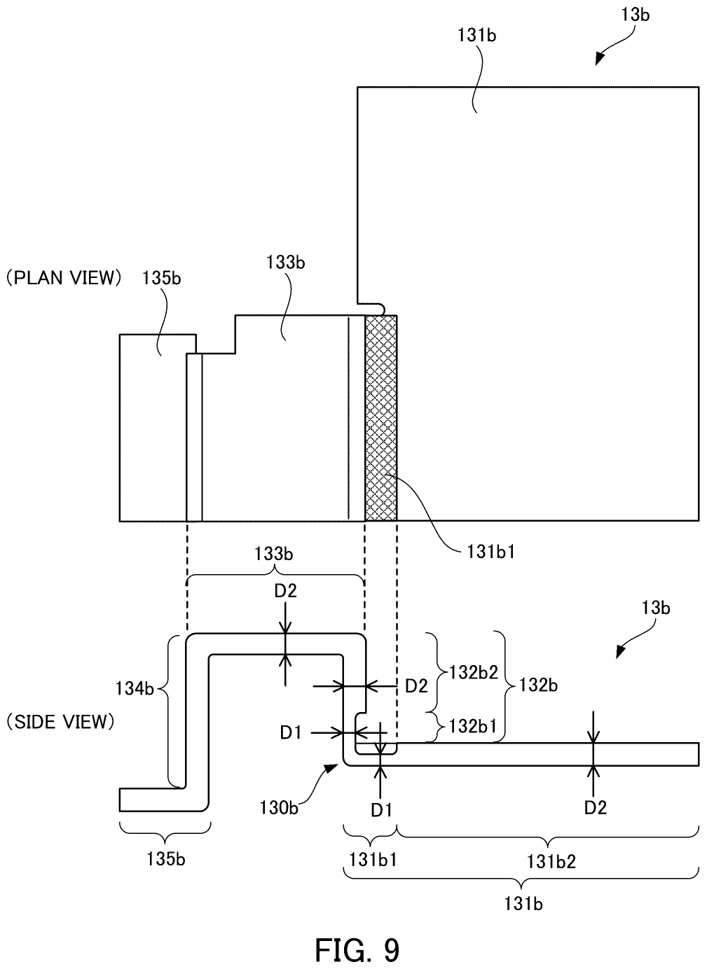

FIG. 9 is a plan view and a side view illustrating a second example of the configuration of the wiring member. In the wiring member 13b illustrated in FIG. 9, the bridge portion 133b, the second rising portion 134b, and the second bonding portion 135b have the thickness D2 (second thickness), as in FIG. 5.

The second example configuration illustrated in FIG. 9 is different from the first example configuration illustrated in FIG. 6 in that, only a connection region 131b1 of the first bonding portion 131b connected to the connecting portion 130b has the thickness D1, and the other region 131b2 thereof has the thickness D2 (>D1). In the plan view of FIG. 9, the connection region 131b1 having the thickness D1 in the first bonding portion 131b is hatched.

In the second example configuration, the vicinity region of the connecting portion 130b has a reduced thickness, so that the connecting portion 130b has a reduced bending rigidity, as in the first example configuration. As a result, the amount of deformation (the amount of expansion and contraction) due to temperature changes in the vicinity region of the connecting portion 130b is reduced, and thus the stress applied to the bonding material 14a from the first bonding portion 131b is reduced. In addition, the bending angle at the connecting portion 130b when deformation occurs in the first bonding portion 131b due to expansion and contraction increases. Therefore, in particular, stress applied to the bonding material 14a from the portion of the first bonding portion 131b connected to the first rising portion 132b is reduced. As a result, it is possible to reduce the likelihood that a crack occurs in the bonding material 14a corresponding to that portion and the likelihood that the crack develops.

In addition, since the thin region (the region having the thickness D1) in the first bonding portion 131b is smaller than that in the first example configuration, the amount of the Joule heat generated when a current flows through the wiring member 13b is reduced.

The region 131b2 of the first bonding portion 131b does not need to have the thickness D2, and may have a thickness greater than D1 and less than D2. That is, the thickness of the region 131b2 of the first bonding portion 131b other than the connection region 131b1 connected to the connecting portion 130b may be greater than the thickness of the connection region 131b1 and less than the thicknesses of the bridge portion 133b, the second rising portion 134b, and the second bonding portion 135b.

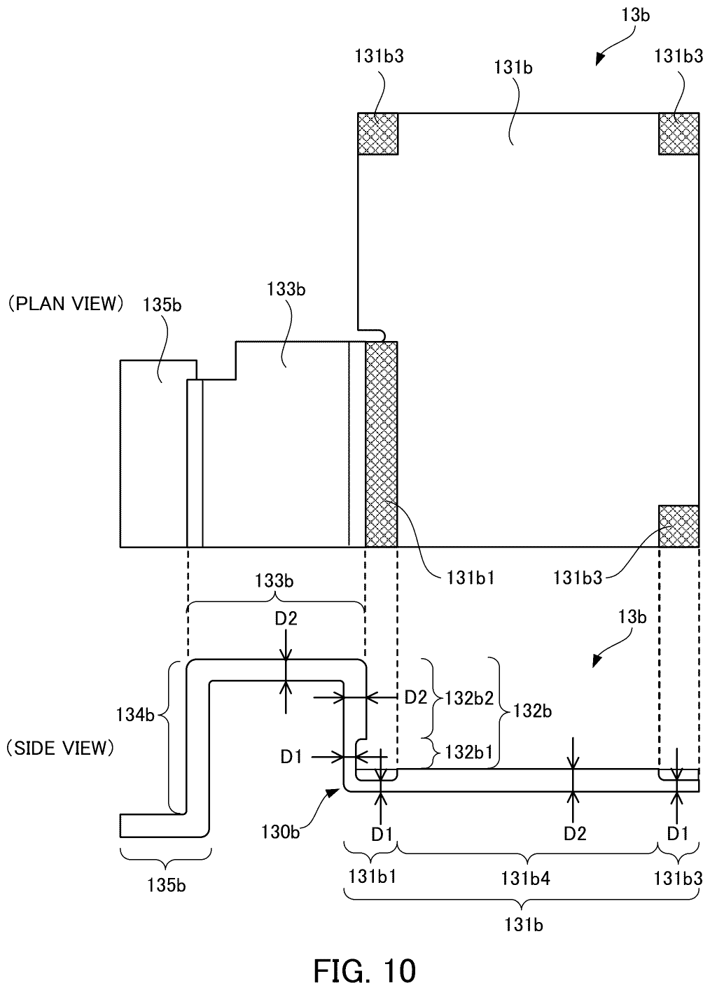

FIG. 10 is a plan view and a side view of a third example of the configuration of the wiring member. In the wiring member 13b illustrated in FIG. 10, the bridge portion 133b, the second rising portion 134b, and the second bonding portion 135b have the thickness D2 (second thickness), as in FIG. 5.

In the third example configuration illustrated in FIG. 10, the connection region 131b1 of the first bonding portion 131b connected to the connecting portion 130b has the thickness of D1, as in the second example configuration illustrated in FIG. 9. In addition, three corner regions 131b3 of the first bonding portion 131b, which has a rectangular shape in plan view, also have the thickness D1, and a region 131b4 excluding the connection region 131b1 and the corner regions 131b3 has the thickness D2 (>D1). That is, in the first bonding portion 131b, the thickness of the connection region 131b1 connected to the connecting portion 130b and the thicknesses of the three corner regions 131b3 are less than the thickness of the region 131b4 excluding the connection region 131b1 and the corner regions 131b3.

In the plan view of FIG. 10, the regions of the thickness D1 in the first bonding portion 131b are hatched. In addition, since the other corner region of the first bonding portion 131b is included in the connection region 131b1, it is said that the four corner regions of the first bonding portion 131b have the thicknesses D1 in the third example configuration.

When expansion and contraction occur in the first bonding portion 131b due to temperature changes, a crack in the bonding material 14a is likely to occur in a region close to the outer periphery of the first bonding portion 131b in plan view, particularly in a corner region. The reduction in the thicknesses of the corner regions of the first bonding portion 131b as in the third example configuration makes it possible to reduce the likelihood that a crack occurs in the bonding material 14a.

The thickness of the region 131b4 of the first bonding portion 131b is not necessarily D2, and may be greater than D1 and less than D2. That is, the thickness of the region 131b4 may be greater than the thicknesses of the connection region 131b1 connected to the connecting portion 130b and the three corner regions 131b3 and less than the thicknesses of the bridge portion 133b, the second rising portion 134b, and the second bonding portion 135b. The thickness of the corner regions 131b3 of the first bonding portion 131b other than the corner region included in the connection region 131b1 are not necessarily the same as that of the connection region 131b1, as long as it is less than the thickness of the region 131b4.

Although not illustrated, the thicknesses of the edge regions along the four sides of the first bonding portion 131b in plan view may be made less than the thickness of the other region.

### Second Embodiment

In a semiconductor device 1 according to a second embodiment, the ratios of the areas of the first bonding portions 131a and 131b of the wiring members 13a and 13b to the areas of active portions of the semiconductor chips 12a and 12b are optimized so as to reduce the likelihood that cracks occur in a bonding material bonded to the first bonding portions 131a and 131b due to temperature changes. In the following description, the same components as those in the first embodiment are denoted by the same reference numerals, and the description thereof will be omitted.

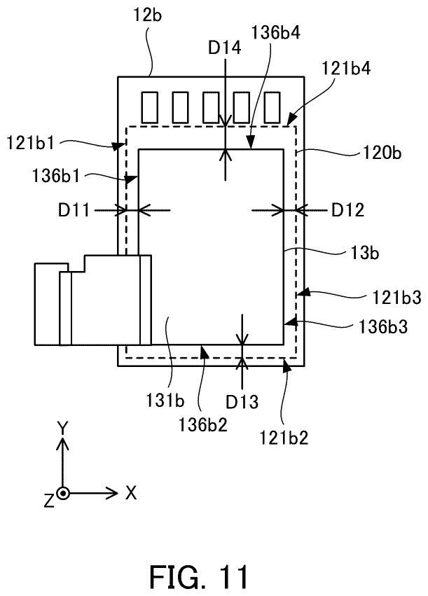

FIG. 11 illustrates the sizes of a semiconductor chip and a wiring member according to the second embodiment. FIG. 11 is a plan view of the semiconductor chip 12b and the wiring member 13b included in the semiconductor unit 10. The following description of the present embodiment is about the relationship between the semiconductor chip 12b and the wiring member 13b, but the same applies to the relationship between the semiconductor chip 12a and the wiring member 13a.

The semiconductor chip 12b includes an active portion 120b. The active portion 120b is a region in which a main current flows between the upper surface (surface on the +Z side) and the lower surface (surface on the −Z side) of the semiconductor chip 12b. In the case where the semiconductor chip 12b includes an RC-IGBT as a power device element, the active portion 120b includes a transistor element (IGBT) region and a diode element (FWD) region. The active portion 120b has a rectangular shape in plan view, and is formed, for example, in a region including the emitter electrode 12b2 provided on the upper surface of the semiconductor chip 12b. Further, the active portion 120b includes a guard ring (not illustrated) formed at the edge portion thereof.

As illustrated in FIG. 11, the four sides (end sides) of the active portion 120b having a rectangular shape in plan view are referred to as sides 121b1, 121b2, 121b3, and 121b4 in order counterclockwise from the left side (the −X side) in FIG. 11. The four sides (end sides) of the first bonding portion 131b having a rectangular shape in plan view are referred to as sides 136b1, 136b2, 136b3, and 136b4 in order counterclockwise from the left side (the −X side) in FIG. 11.

The first bonding portion 131b of the wiring member 13b is disposed in the region of the active portion 120b in plan view such that the sides 136b1, 136b2, 136b3, and 136b4 of the first bonding portion 131b are parallel to the sides 121b1, 121b2, 121b3, and 121b4 of the active portion 120b, respectively. As illustrated in FIG. 11, the gaps between the sides 136b1, 136b2, 136b3, and 136b4 of the first bonding portion 131b and their corresponding sides 121b1, 121b2, 121b3, and 121b4 of the active portion 120b are denoted by D11, D13, D12, and D14, respectively.

In the second embodiment, among the gaps D11, D12, D13, and D14, at least the gaps D11, D12, and D13 are equal to each other. However, the gaps D11, D12, D13, and D14 may have different dimensions.

Here, the crack tolerance length and the fillet angle of the bonding material 14b that bonds the first bonding portion 131b to the upper surface of the semiconductor chip 12b are determined based on the relationship of the area between the active portion 120b and the first bonding portion 131b and the relationship of the gaps D11, D12, D13, and D14. When the area of the first bonding portion 131b is increased relative to the active portion 120b to reduce the gaps D11, D12, D13, and D14, the crack tolerance length is increased, and the lifetime of the semiconductor module 2 is extended. However, the fillet angle of the bonding material 14b becomes steep (the angle with respect to the X-Y plane is close to 90 degrees). Therefore, the stress applied to the bonding material 14b by the expansion and contraction of the first bonding portion 131b due to temperature changes is concentrated in the vicinity of the end portion of the active portion 120b. As a result, the stress strain of the emitter electrode 12b2 provided on the upper surface (surface on the +Z side) of the active portion 120b increases, and the semiconductor chip 12b is more likely to fail. On the other hand, when the area of the first bonding portion 131b is reduced relative to the active portion 120b to increase the gaps D11, D12, D13, and D14, the power cycle resistance is reduced and the lifetime of the semiconductor module 2 is shortened.

As described above, there is a trade-off relationship between the extension in the lifetime due to the increase in the area ratio of the first bonding portion 131b to the active portion 120b and the suppression of the stress strain of the electrode due to the decrease in the area ratio. Therefore, it is desirable that the area ratio and the gaps D11, D12, D13, and D14 are set within optimal ranges so that the advantages of both are obtained in a well-balanced manner.

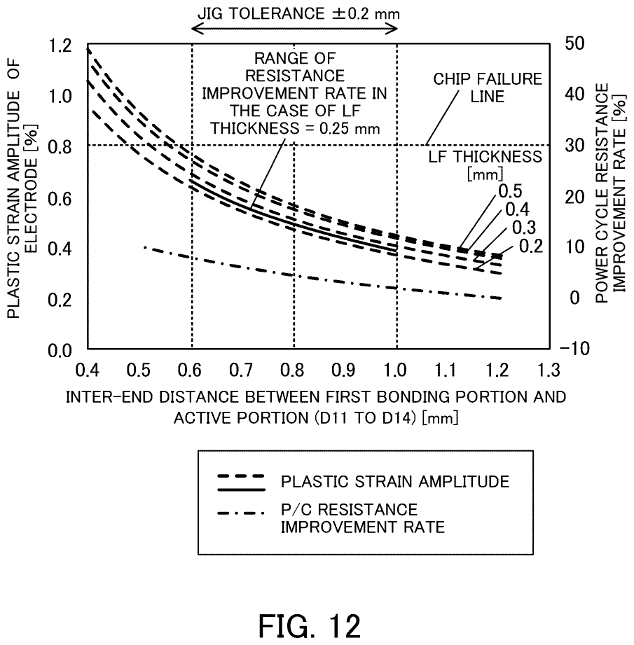

FIG. 12 is a graph representing the relationship between the inter-end distance between a first bonding portion and an active portion and the plastic strain amplitude of an electrode and the relationship between the inter-end distance and the power cycle resistance improvement rate, with respect to the case of FIG. 11. In FIG. 12, as an example, the semiconductor chip 12b with the active portion 120b having a size of 13.85 mm×10.5 mm is used, and the first example configuration illustrated in FIG. 5 is adopted as the wiring member 13b. Further, the inter-end distance on the horizontal axis in FIG. 12 indicates the gaps D11, D12, D13, and D14. Here, D11=D12=D13.

FIG. 12 represents the plastic strain amplitudes of the electrode (the emitter electrode 12b2 of the semiconductor chip 12b) for cases where a lead frame (LF) thickness is 0.2 mm, 0.3 mm, 0.4 mm, and 0.5 mm. The LF thickness here refers to the thickness D1 of the wiring member 13b configured as illustrated in FIG. 5. According to the graph of FIG. 12, the plastic strain amplitude of the electrode decreases as the inter-end distance increases. The plastic strain amplitude of the electrode decreases as the LF thickness decreases. On the other hand, according to the graph of FIG. 12, the power cycle resistance improvement rate increases as the inter-end distance decreases.

In the range of the power cycle resistance improvement rate based on the LF thickness=0.25 mm used as the reference value in the above-described first embodiment, it is desirable to set the optimal range of the inter-end distance to 0.6 mm to 1.0 mm, inclusive, in consideration of a jig tolerance of #0.2 mm on the basis of the inter-end distance of 0.8 mm at which the plastic strain amplitude of the electrode is sufficiently below the chip failure line while maintaining the power cycle resistance improvement rate. That is, it is desirable that the area and the lengths of the long side and the short side of the first bonding portion 131b are determined so that at least the gaps D11, D12, and D13 among the gaps D11, D12, D13, and D14 fall within the above optimal range. If the inter-end distance is less than 0.6 mm, the plastic strain amplitude of the electrode exceeds the chip failure line. In this case, the stress strain of the emitter electrode 12b2 provided on the upper surface (surface on the +Z side) of the active portion 120b increases, so that the semiconductor chip 12b is more likely to fail. If the inter-end distance is greater than 1.0 mm, on the other hand, the crack tolerance length of the bonding material 14b is shortened, which results in a lower power cycle resistance improvement rate, thereby reducing the expected lifetime of the semiconductor module 2.

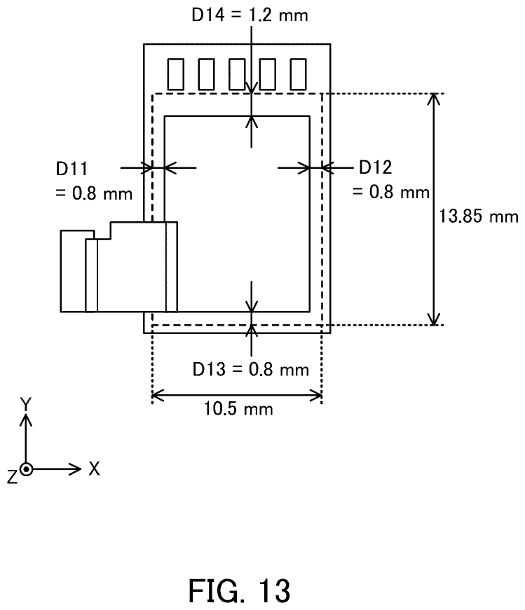

FIG. 13 illustrates an example of the sizes of the semiconductor chip and the wiring member according to the second embodiment.

As an example, when the size of the active portion 120b is set to 13.85 mm×10.5 mm as described above and the gaps D11, D12, D13, and D14 are set within the above-described optimal range, the area ratio of the first bonding portion 131b to the active portion 120b falls within the range of 69% to 81%, inclusive. That is, by setting the area ratio of the first bonding portion 131b to the active portion 120b within the range of 69% to 81%, inclusive, it is possible to allow for a gentle fillet angle of the bonding material 14b while increasing the crack tolerance length of the bonding material 14b to some extent. This makes it possible to reduce the likelihood of a crack occurring in the bonding material 14b and also reduce the likelihood of the generation of the stress strain in the emitter electrode 12b2 of the semiconductor chip 12b, which in turn allows for an extension in the lifetime of the semiconductor module 2.

### Third Embodiment

Cracks are more likely to occur in the bonding material that bonds the semiconductor chips 12a and 12b to the corresponding wiring members 13a and 13b as the difference expansion coefficient between the semiconductor chips 12a and 12b and the wiring members 13a and 13b increases. Therefore, by making the linear expansion coefficients of the wiring members 13a and 13b closer to (i.e., making smaller) the linear expansion coefficients of the semiconductor chips 12a and 12b, it is possible to reduce the likelihood of cracks occurring in the bonding material.

In the present embodiment, at least a part of each of the first bonding portions 131a and 131b of the wiring members 13a and 13b is formed as a laminated region in which a plurality of members having different linear expansion coefficients are stacked. Accordingly, the overall linear expansion coefficient in the laminated region is reduced, thereby decreasing the difference in the amount of thermal expansion between the first bonding portions 131a and 131b and the corresponding semiconductor chips 12a and 12b. As a result, the likelihood of cracks occurring in the bonding material is reduced.

In the following description, the same components as those in the first and second embodiments are denoted by the same reference numerals, and the description thereof will be omitted. The following description is about the wiring member 13b bonded to the semiconductor chip 12b, but the same applies to the wiring member 13a bonded to the semiconductor chip 12a.

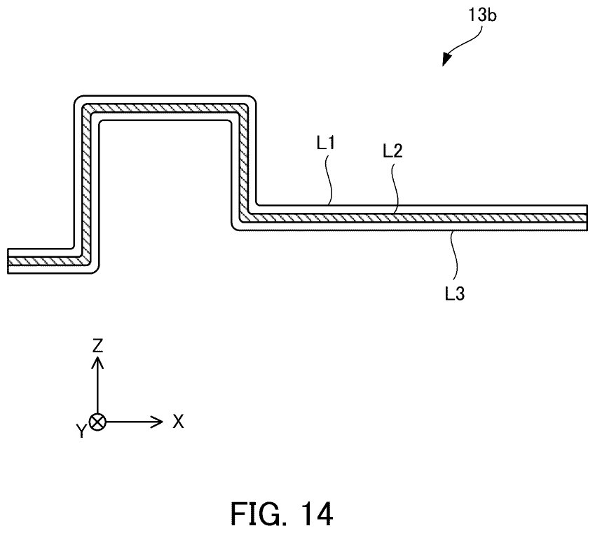

FIG. 14 is a sectional view illustrating a first example of a laminated structure of the wiring member. The entire wiring member 13b illustrated in FIG. 14 has a three-layer structure including an upper layer L1, an intermediate layer L2, and a lower layer L3. In addition, as an example, the upper layer L1 and the lower layer L3 are formed of copper, and the intermediate layer L2 is formed of a nickel-iron alloy (for example, an Invar alloy) having a lower linear expansion coefficient than copper. Alternatively, the intermediate layer L2 may be formed of, for example, a non-metal material such as carbon.

The wiring member 13b having such a laminated structure has a linear expansion coefficient close to the linear expansion coefficient of the semiconductor chip 12b, compared to the case where the entire wiring member 13b is formed of copper. As a result, the amount of expansion and contraction of the wiring member 13b due to temperature changes is suppressed, thereby reducing the likelihood of a crack occurring in the bonding material 14a that bonds the first bonding portion 131b to the semiconductor chip 12b.

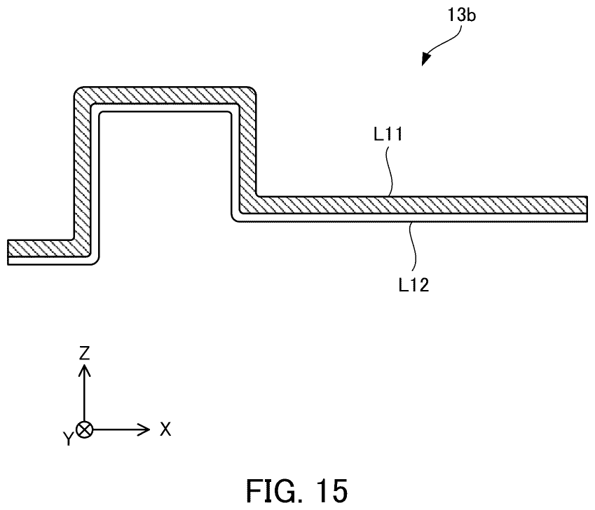

FIG. 15 is a sectional view illustrating a second example of the laminated structure of the wiring member. The entire wiring member 13b illustrated in FIG. 15 has a two-layer structure including an upper layer L11 and a lower layer L12. In addition, as an example, the lower layer L12 is formed of copper, and the upper layer L11 is formed of a nickel-iron alloy (for example, an Invar alloy) having a lower linear expansion coefficient than copper. Alternatively, the upper layer L11 may be formed of, for example, a non-metal material such as carbon.

The wiring member 13b having such a laminated structure has a linear expansion coefficient close to the linear expansion coefficient of the semiconductor chip 12b, compared to the case where the entire wiring member 13b is formed of copper. In addition, by using a material having poor solder wettability, such as a nickel-iron alloy, for the upper layer L11, it is possible to control the upward flow of the bonding material on the underside of the first bonding portions 131a and 131b. As a result, it is possible to reduce the likelihood of a crack occurring in the bonding material 14a that bonds the first bonding portion 131b to the semiconductor chip 12b.

For example, the wiring member 13b may be formed such that only the region corresponding to the first bonding portion 131b has a two-layer structure including the upper layer L11 and the lower layer L12 and the other region has a single-layer structure using the same material as the lower layer L12.

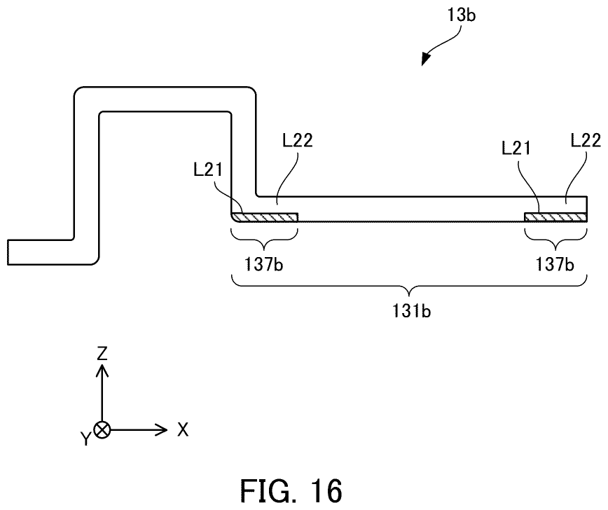

FIG. 16 is a sectional view illustrating a third example of the laminated structure of the wiring member. The wiring member 13b illustrated in FIG. 16 is formed such that only some parts of the first bonding portion 131b each have a laminated region 137b and the remaining part thereof is a single-layer region formed of a single member. The laminated region 137b here is a region where members having different linear expansion coefficients are stacked.

The laminated region 137b includes a first layer L21 (lower layer) stacked on the side facing the emitter electrode 12b2 of the semiconductor chip 12b and a second layer L22 (upper layer) stacked on the opposite side. The first layer L21 is formed of a member (first member) having a lower linear expansion coefficient than the member (second member) of the second layer L22. The single-layer region of the wiring member 13b, other than the laminated region 137b, is formed of a member having a higher linear expansion coefficient than the first layer L21 in the laminated region 137b.

As an example, the single-layer region may be formed of the same member as the second layer L22 of the laminated region 137b. For example, the second layer L22 of the laminated region 137b and the single-layer region may be formed of copper, and the first layer L21 of the laminated region 137b may be formed of a nickel-iron alloy (for example, an Invar alloy). The first layer L21 may be formed of, for example, a non-metal material such as carbon.

In the above laminated region 137b, a layer formed of a material having a linear expansion coefficient close to that of the semiconductor chip 12b is disposed on the side facing the semiconductor chip 12b. Therefore, the amount of expansion and contraction of the surface of the laminated region 137b located on the side facing the semiconductor chip 12b is made close to the amount of expansion and contraction of the semiconductor chip 12b. As a result, it is possible to reduce the likelihood of a crack occurring in the bonding material 14a between the laminated region 137b of the first bonding portion 131b and the semiconductor chip 12b.

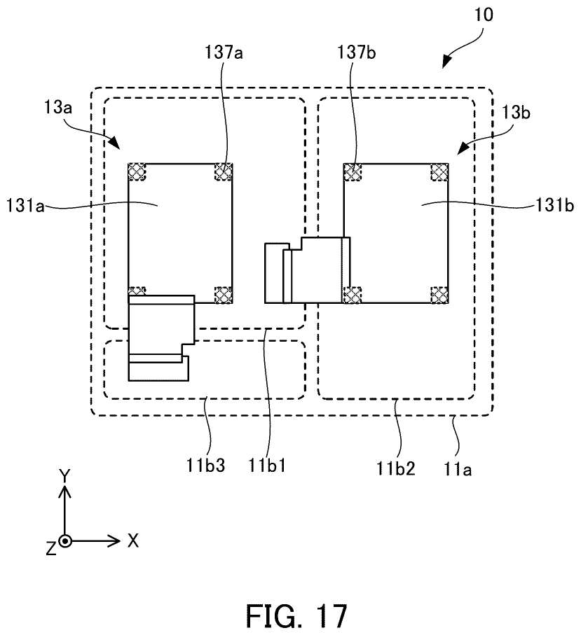

Hereinafter, examples of an arrangement of laminated regions 137a and 137b in the wiring members 13a and 13b will be described with reference to FIGS. 17 to 19. Like the wiring member 13b, a laminated region 137a of the wiring member 13a includes a first layer L21 (lower layer) stacked on the side facing the emitter electrode 12a2 of the semiconductor chip 12a and a second layer L22 (upper layer) stacked on the opposite side. Further, in FIGS. 17 to 19, the laminated regions 137a and 137b in the wiring members 13a and 13b are hatched, and the single-layer regions are indicated as white regions.

FIG. 17 is a plan view illustrating a first example of an arrangement of laminated regions in the wiring members. In FIG. 17, the laminated regions 137a and 137b are formed at corner portions of the first bonding portions 131a and 131b, which are rectangular, in the wiring members 13a and 13b.

As described earlier, when expansion and contraction of the first bonding portions 131a and 131b occur due to temperature changes, cracks that occur in the bonding material on the underside (on the −Z side) of the first bonding portions 131a and 131b are likely to occur from regions close to the corner portions of the first bonding portions 131a and 131b in plan view. By forming the laminated regions 137a and 137b at the corner portions of the first bonding portions 131a and 131b as illustrated in FIG. 17, the corner portions of the first bonding portions 131a and 131b have linear expansion coefficients close to those of the semiconductor chips 12a and 12b, thereby reducing the likelihood of cracks occurring in the bonding material on the underside of the first bonding portions 131a and 131b.

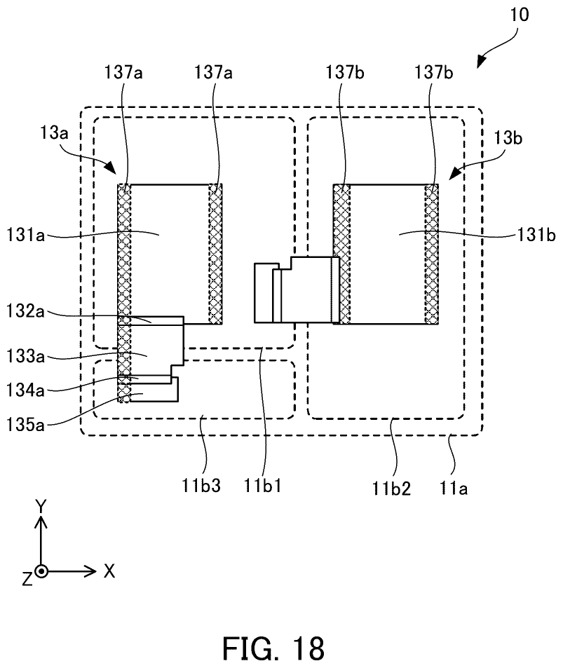

FIG. 18 is a plan view illustrating a second example of the arrangement of the laminated regions in the wiring members. In FIG. 18, the laminated regions 137a and 137b are formed at the opposing edge portions of the first bonding portions 131a and 131b, which are rectangular, in the wiring members 13a and 13b. In FIG. 18, the laminated regions 137a and 137b are formed at the edge portions of the first bonding portions 131a and 131b facing each other in the ±X direction.

Further, in the wiring member 13a, the laminated region 137a is also formed at the −X-side edge portions of the first rising portion 132a, the bridge portion 133a, the second rising portion 134a, and the second bonding portion 135a. For example, the wiring members 13a and 13b may be manufactured by cutting out the shapes of the wiring members 13a and 13b from one flat plate member in which the laminated regions 137a and 137b are formed at the opposing edge portions and then bending the cut-out flat plate members.

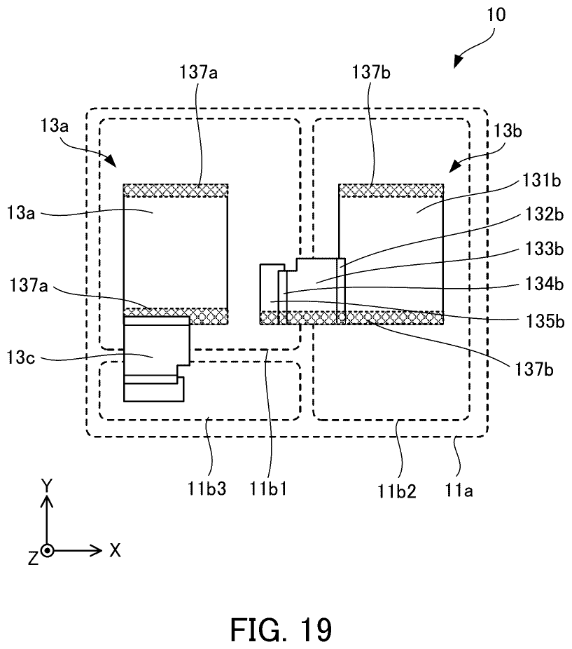

FIG. 19 is a plan view illustrating a third example of the arrangement of the laminated regions in the wiring members. In FIG. 19, the laminated regions 137a and 137b are formed at the opposing edge portions of the first bonding portions 131a and 131b, which are rectangular, in the wiring members 13a and 13b, as in FIG. 18. However, in FIG. 19, the laminated regions 137a and 137b are formed at the edge portions of the first bonding portions 131a and 131b facing each other in the ±Y direction.

Further, in the wiring member 13b, the laminated region 137b is also formed at the −Y-side edge portions of the first rising portion 132b, the bridge portion 133b, the second rising portion 134b, and the second bonding portion 135b. For example, the wiring members 13a and 13b may be manufactured by cutting out the shapes of the wiring members 13a and 13b from one flat plate member in which the laminated regions 137a and 137b are formed at the opposing edge portions and then bending the cut-out flat plate members.

In both FIGS. 18 and 19, the laminated regions 137a and 137b are formed to include the corner portions of the first bonding portions 131a and 131b.

As described above, when expansion and contraction occur in the first bonding portions 131a and 131b due to temperature changes, cracks that occur in the bonding material on the underside (on the −Z side) of the first bonding portions 131a and 131b are likely to occur from regions close to the outer peripheries of the first bonding portions 131a and 131b in plan view. As illustrated in FIGS. 18 and 19, the laminated regions 137a and 137b are formed at the edge portions of the first bonding portions 131a and 131b, so that it is possible to reduce the likelihood of cracks occurring in the bonding material on the underside of the first bonding portions 131a and 131b.

In addition, by forming the first layers L21 of the laminated regions 137a and 137b using a material with poor solder wettability such as a nickel-iron alloy, it is possible to suppress the wetting and spreading of the bonding material at the end portions of the first bonding portions 131a and 131b where the laminated regions 137a and 137b are located.

In each laminated region 137a and 137b, the positions of the first layer L21 and the second layer L22 may be reversed. In this case, by forming the first layer L21 using a material with poor solder wettability such as a nickel-iron alloy, it is possible to control the upward flow of the bonding material at the end portions of the first bonding portions 131a and 131b where the laminated regions 137a and 137b are located.

At least two configurations may be combined from among the configurations of the wiring members 13a and 13b in the first embodiment, the configurations of the semiconductor chips 12a and 12b and the wiring members 13a and 13b in the second embodiment, and the configurations of the wiring members 13a and 13b in the third embodiment. For example, the wiring member 13b may be formed so that the thickness of the lower region 132b1 of the first rising portion 132b connected to the connecting portion 130b and the thickness of the connecting portion 130b may be made less than the thickness of the upper region 132b2 located above the lower region 132b1, and the area ratio of the first bonding portion 131b to the active portion 120b may be set within the range of 69% to 81%, inclusive.

Further, the wiring member 13b may be formed so that, for example, the thickness of the lower region 132b1 of the first rising portion 132b connected to the connecting portion 130b and the thickness of the connecting portion 130b is less than the thickness of the upper region 132b2 located above the lower region 132b1, and at least a part of each first bonding portion 131a and 131b of the wiring members 13a and 13b may be formed as a laminated region in which a plurality of members having different linear expansion coefficients are stacked. For example, the area ratio of the first bonding portion 131b to the active portion 120b may be set within the range of 69% to 81%, inclusive, and at least a part of each first bonding portion 131a and 131b of the wiring members 13a and 13b may be formed as a laminated region in which a plurality of members having different linear expansion coefficients are stacked.

The disclosed techniques make it possible to reduce the likelihood of damage to a bonding material bonding a semiconductor chip to a wiring member.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor chip including an electrode on an upper surface thereof; and
a wiring member including a bonding portion, a rising portion, and a connecting portion, the bonding portion being bonded to the electrode via a bonding material, the rising portion being of a shape of a flat plate and extending upward from the bonding portion, the connecting portion connecting the bonding portion to the rising portion, wherein
the rising portion includes a lower region connected to the connecting portion and an upper region located above the lower region, and
both the lower region and the connecting portion have a first thickness, and the upper region has a second thickness that is larger than the first thickness.

2. The semiconductor device according to claim 1, wherein an overall thickness of the bonding portion is less than the second thickness.

3. The semiconductor device according to claim 1, wherein
the bonding portion includes a first region connected to the connecting portion and a second region different from the first region, and
a thickness of the first region is less than a thickness of the second region.

4. The semiconductor device according to claim 1, wherein
the bonding portion is rectangular in a plan view of the semiconductor device, a corner thereof being a corner region of the bonding portion;
the bonding portion further includes a first region connected to the connecting portion, and a second region different from the corner region and the region, and
each of a thickness of the corner region and a thickness of the first region is less than a thickness of the second region.

5. The semiconductor device according to claim 1, wherein
the semiconductor chip includes an active portion, and the electrode is formed on the active portion, and
in a plan view of the semiconductor device, an area of the bonding portion is 69% or more and 81% or less of an area of the active portion.

6. The semiconductor device according to claim 1, wherein the bonding portion includes a laminated region in which a plurality of members having different linear expansion coefficients are stacked.

7. A semiconductor device, comprising:
a semiconductor chip including an active portion and an electrode, the electrode being provided on an upper surface of the semiconductor chip and inside the active portion in a plan view of the semiconductor device; and
a wiring member including a bonding portion and a rising portion extending from an end portion of the bonding portion, the bonding portion having a bonding surface on a lower surface thereof, the bonding surface being bonded to the electrode via a bonding material and being located inside the active portion in the plan view, wherein
in the plan view, an area of the bonding portion is 69% or more and 81% or less of an area of the active portion.

8. The semiconductor device according to claim 7, wherein
the active portion and the bonding portion are each rectangular in the plan view,
the bonding portion is located inside the active portion in the plan view, and
a distance from a side of the active portion to a side of the bonding portion facing the side of the active portion is in a range of 0.6 mm to 1.0 mm, inclusive.

9. The semiconductor device according to claim 7, wherein the bonding portion includes a laminated region in which a plurality of members having different linear expansion coefficients are stacked.

10. A semiconductor device, comprising:
a semiconductor chip including an electrode on an upper surface thereof; and
a wiring member including a bonding portion and a rising portion extending from an end portion of the bonding portion, the bonding portion being of a shape of a flat plate and being bonded to the electrode via a bonding material, wherein
the bonding portion includes a laminated region in which a plurality of members having different linear expansion coefficients are stacked.

11. The semiconductor device according to claim 10, wherein
the bonding portion is rectangular in a plan view of the semiconductor device, a corner thereof being a corner region of the bonding portion; and
the laminated region includes the corner portion in the plan view.

12. The semiconductor device according to claim 11, wherein
the laminated region of the bonding portion includes
a first layer stacked on a side of the bonding portion facing the electrode of the semiconductor chip, and
a second layer stacked on a side of the first layer opposite to the electrode, and
the second layer is formed of a member having a linear expansion coefficient higher than a linear expansion coefficient of a member of the first layer.

13. The semiconductor device according to claim 11, wherein
the bonding portion has two opposing edge portions in the plan view, and
the laminated region is provided at each of the edge portions of the bonding portion.

14. The semiconductor device according to claim 10, wherein
the laminated region has a two-layer structure including a first layer and a second layer, the first layer using a first member, the second layer using a second member having a linear expansion coefficient higher than a linear expansion coefficient of the first member, and
the bonding portion further has a region, different from the laminated region, in the plan view, the region being of a single-layer structure and including the second member.
